(19) United States
(12) Patent Application Publication
(10) Pub. No.: US 2026/0173514 A1
(43) Pub. Date: Jun. 18, 2026

(54) AIR-GAP ISOLATED STACKED SEMICONDUCTOR DEVICE ARCHITECTURE

(71) Applicant: International Business Machines Corporation, Armonk, NY (US)

(72) Inventors: WuKang Kim, Troy, NY (US); Chen Zhang, Santa Clara, CA (US); Abir Shadman, Albany, NY (US); Utkarsh Bajpai, Suffern, NY (US); Junli Wang, Slingerlands, NY (US)

(21) Appl. No.: 18/980,334

(22) Filed: Dec. 13, 2024

(51) Int. Cl. H10D 84/85; H10D 84/01

(52) U.S. Cl. CPC H10D 84/851; H10D 84/0186; H10D 84/0188

(57) ABSTRACT

A semiconductor device includes a first transistor including a first source/drain region and a second transistor, vertically stacked on the first transistor, including a second source/drain region. The semiconductor device includes an isolation layer positioned between the first transistor and the second transistor and an air gap positioned between the first source/drain region and the isolation layer.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture.

In an illustrative embodiment, a semiconductor device includes a first transistor including a first source/drain region and a second transistor, vertically stacked on the first transistor, including a second source/drain region. The semiconductor device includes an isolation layer positioned between the first transistor and the second transistor and an air gap positioned between the first source/drain region and the isolation layer.

In another illustrative embodiment, a semiconductor device includes an L-shaped stacked transistor architecture comprising a first transistor having a first source/drain region and a second transistor having a second source/drain region. The semiconductor device further includes an isolation layer positioned between the first transistor and the second transistor, and an air gap positioned between a portion of the first source/drain region and the isolation layer.

In another exemplary embodiment, a method includes forming a first transistor comprising a first source/drain region, forming a sacrificial layer over the first source/drain region, and forming a second transistor, vertically stacked over the first transistor, comprising a second source/drain region. The method includes removing the sacrificial layer to form an opening between the first source/drain region and an isolation layer positioned between the first transistor and the second transistor and forming a source/drain contact connected to the first source/drain region, where the source/drain contact partially fills the opening, thereby creating an air gap between at least a top side of the first source/drain region and the isolation layer.

Other embodiments will be described in the following detailed description of embodiments, which is to be read in conjunction with the accompanying figures.

### BRIEF DESCRIPTION OF THE DRAWINGS

FIG. 1 depicts a top view of a semiconductor structure with lines A, B, C, and D on which the cross-sectional views of FIGS. 2A-19 are based, according to an illustrative embodiment.

FIG. 2A depicts a first cross-sectional view corresponding to line A in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line B in FIG. 1 illustrating the semiconductor structure of FIG. 1 during the intermediate step of the method of fabricating the nanosheet transistor structure, according to an illustrative embodiment.

FIG. 2C depicts a third cross-sectional view corresponding to line C in FIG. 1 illustrating the semiconductor structure of FIG. 1 during the intermediate step of the method of fabricating the nanosheet transistor structure, according to an illustrative embodiment.

FIG. 2D depicts a fourth cross-sectional view corresponding to line D in FIG. 1 illustrating the semiconductor structure of FIG. 1 during the intermediate step of the method of fabricating the nanosheet transistor structure, according to an illustrative embodiment.

FIG. 3A depicts a first cross-sectional view corresponding to line A in FIG. 1 following formation of a dielectric layer, according to an illustrative embodiment.

FIG. 3B depicts a second cross-sectional view corresponding to line B in FIG. 1 following the formation of the dielectric layer, according to an illustrative embodiment.

FIG. 3C depicts a third cross-sectional view corresponding to line C in FIG. 1 following the formation of the dielectric layer, according to an illustrative embodiment.

FIG. 3D depicts a fourth cross-sectional view corresponding to line D in FIG. 1 following the formation of the dielectric layer, according to an illustrative embodiment.

FIG. 4A depicts a first cross-sectional view corresponding to line A in FIG. 1 following recessing of the dielectric layer, according to an illustrative embodiment.

FIG. 4B depicts a second cross-sectional view corresponding to line B in FIG. 1 following the recessing of the dielectric layer, according to an illustrative embodiment.

FIG. 4C depicts a third cross-sectional view corresponding to line C in FIG. 1 following the recessing of the dielectric layer, according to an illustrative embodiment.

FIG. 4D depicts a fourth cross-sectional view corresponding to line D in FIG. 1 following the recessing of the dielectric layer, according to an illustrative embodiment.

FIG. 5A depicts a first cross-sectional view corresponding to line A in FIG. 1 following formation of a blocking spacer layer, according to an illustrative embodiment.

FIG. 5B depicts a second cross-sectional view corresponding to line B in FIG. 1 following the formation of the blocking spacer layer, according to an illustrative embodiment.

FIG. 5C depicts a third cross-sectional view corresponding to line C in FIG. 1 following the formation of the blocking spacer layer, according to an illustrative embodiment.

FIG. 5D depicts a fourth cross-sectional view corresponding to line D in FIG. 1 following the formation of the blocking spacer layer, according to an illustrative embodiment.

FIG. 6A depicts a first cross-sectional view corresponding to line A in FIG. 1 following partial removal of the blocking spacer layer and removal of the dielectric layer, according to an illustrative embodiment.

FIG. 6B depicts a second cross-sectional view corresponding to line B in FIG. 1 following the partial removal of the blocking spacer layer and the removal of the dielectric layer, according to an illustrative embodiment.

FIG. 6C depicts a third cross-sectional view corresponding to line C in FIG. 1 following the partial removal of the blocking spacer layer and the removal of the dielectric layer, according to an illustrative embodiment.

FIG. 6D depicts a fourth cross-sectional view corresponding to line D in FIG. 1 following the partial removal of the blocking spacer layer and the removal of the dielectric layer, according to an illustrative embodiment.

FIG. 7A depicts a first cross-sectional view corresponding to line A in FIG. 1 following bottom source/drain region formation, according to an illustrative embodiment.

FIG. 7B depicts a second cross-sectional view corresponding to line B in FIG. 1 following the bottom source/drain region formation, according to an illustrative embodiment.

FIG. 7C depicts a third cross-sectional view corresponding to line C in FIG. 1 following the bottom source/drain region formation, according to an illustrative embodiment.

FIG. 7D depicts a fourth cross-sectional view corresponding to line D in FIG. 1 following the bottom source/drain region formation, according to an illustrative embodiment.

FIG. 8A depicts a first cross-sectional view corresponding to line A in FIG. 1 following sacrificial layer formation, according to an illustrative embodiment.

FIG. 8B depicts a second cross-sectional view corresponding to line B in FIG. 1 following the sacrificial layer formation, according to an illustrative embodiment.

FIG. 8C depicts a third cross-sectional view corresponding to line C in FIG. 1 following the sacrificial layer formation, according to an illustrative embodiment.

FIG. 8D depicts a fourth cross-sectional view corresponding to line D in FIG. 1 following the sacrificial layer formation, according to an illustrative embodiment.

FIG. 9A depicts a first cross-sectional view corresponding to line A in FIG. 1 following interlayer dielectric (ILD) layer and ILD liner formation, according to an illustrative embodiment.

FIG. 9B depicts a second cross-sectional view corresponding to line B in FIG. 1 following the ILD layer and ILD liner formation, according to an illustrative embodiment.

FIG. 9C depicts a third cross-sectional view corresponding to line C in FIG. 1 following the ILD layer and ILD liner formation, according to an illustrative embodiment.

FIG. 9D depicts a fourth cross-sectional view corresponding to line D in FIG. 1 following the ILD layer and ILD liner formation, according to an illustrative embodiment.

FIG. 10A depicts a first cross-sectional view corresponding to line A in FIG. 1 following partial removal of the ILD layer, according to an illustrative embodiment.

FIG. 10B depicts a second cross-sectional view corresponding to line B in FIG. 1 following the partial removal of the ILD layer, according to an illustrative embodiment.

FIG. 10C depicts a third cross-sectional view corresponding to line C in FIG. 1 following the partial removal of the ILD layer, according to an illustrative embodiment.

FIG. 10D depicts a fourth cross-sectional view corresponding to line D in FIG. 1 following the partial removal of the ILD layer, according to an illustrative embodiment.

FIG. 11A depicts a first cross-sectional view corresponding to line A in FIG. 1 following partial removal of the ILD liner, according to an illustrative embodiment.

FIG. 11B depicts a second cross-sectional view corresponding to line B in FIG. 1 following the partial removal of the ILD liner, according to an illustrative embodiment.

FIG. 11C depicts a third cross-sectional view corresponding to line C in FIG. 1 following the partial removal of the ILD liner, according to an illustrative embodiment.

FIG. 11D depicts a fourth cross-sectional view corresponding to line D in FIG. 1 following the partial removal of the ILD liner, according to an illustrative embodiment.

FIG. 12A depicts a first cross-sectional view corresponding to line A in FIG. 1 following further removal of the ILD layer and top source/drain region formation, according to an illustrative embodiment.

FIG. 12B depicts a second cross-sectional view corresponding to line B in FIG. 1 following the further removal of the ILD layer and the top source/drain region formation, according to an illustrative embodiment.

FIG. 12C depicts a third cross-sectional view corresponding to line C in FIG. 1 following the further removal of the ILD layer and the top source/drain region formation, according to an illustrative embodiment.

FIG. 12D depicts a fourth cross-sectional view corresponding to line D in FIG. 1 following the further removal of the ILD layer and the top source/drain region formation, according to an illustrative embodiment.

FIG. 13A depicts a first cross-sectional view corresponding to line A in FIG. 1 following isolation layer formation, according to an illustrative embodiment.

FIG. 13B depicts a second cross-sectional view corresponding to line B in FIG. 1 following the isolation layer formation, according to an illustrative embodiment.

FIG. 13C depicts a third cross-sectional view corresponding to line C in FIG. 1 following the isolation layer formation, according to an illustrative embodiment.

FIG. 13D depicts a fourth cross-sectional view corresponding to line D in FIG. 1 following the isolation layer formation, according to an illustrative embodiment.

FIG. 14A depicts a first cross-sectional view corresponding to line A in FIG. 1 following ILD layer formation and trench formation, according to an illustrative embodiment.

FIG. 14B depicts a second cross-sectional view corresponding to line B in FIG. 1 following the ILD layer formation and the trench formation, according to an illustrative embodiment.

FIG. 14C depicts a third cross-sectional view corresponding to line C in FIG. 1 following the ILD layer formation and the trench formation, according to an illustrative embodiment.

FIG. 14D depicts a fourth cross-sectional view corresponding to line D in FIG. 1 following the ILD layer formation and the trench formation, according to an illustrative embodiment.

FIG. 15A depicts a first cross-sectional view corresponding to line A in FIG. 1 following mask formation and a planarization process, according to an illustrative embodiment.

FIG. 15B depicts a second cross-sectional view corresponding to line B in FIG. 1 following the mask formation and the planarization process, according to an illustrative embodiment.

FIG. 15C depicts a third cross-sectional view corresponding to line C in FIG. 1 following the mask formation and the planarization process, according to an illustrative embodiment.

FIG. 15D depicts a fourth cross-sectional view corresponding to line D in FIG. 1 following the mask formation and the planarization process, according to an illustrative embodiment.

FIG. 16A depicts a first cross-sectional view corresponding to line A in FIG. 1 following a replacement metal gate (RMG) process, according to an illustrative embodiment.

FIG. 16B depicts a second cross-sectional view corresponding to line B in FIG. 1 following the RMG process, according to an illustrative embodiment.

FIG. 16C depicts a third cross-sectional view corresponding to line C in FIG. 1 following the RMG process, according to an illustrative embodiment.

FIG. 16D depicts a fourth cross-sectional view corresponding to line D in FIG. 1 following the RMG process, according to an illustrative embodiment.

FIG. 17A depicts a first cross-sectional view corresponding to line A in FIG. 1 following formation of additional ILD layers and deep trenches, according to an illustrative embodiment.

FIG. 17B depicts a second cross-sectional view corresponding to line B in FIG. 1 following the formation of the additional ILD layers and the deep trenches, according to an illustrative embodiment.

FIG. 17C depicts a third cross-sectional view corresponding to line C in FIG. 1 following the formation of the additional ILD layers and the deep trenches, according to an illustrative embodiment.

FIG. 17D depicts a fourth cross-sectional view corresponding to line D in FIG. 1 following the formation of the additional ILD layers and the deep trenches, according to an illustrative embodiment.

FIG. 18A depicts a first cross-sectional view corresponding to line A in FIG. 1 following further processing steps, according to an illustrative embodiment.

FIG. 18B depicts a second cross-sectional view corresponding to line B in FIG. 1 following the further processing steps, according to an illustrative embodiment.

FIG. 18C depicts a third cross-sectional view corresponding to line C in FIG. 1 following the further processing steps, according to an illustrative embodiment.

FIG. 18D depicts a fourth cross-sectional view corresponding to line D in FIG. 1 following the further processing steps, according to an illustrative embodiment.

FIG. 19 depicts a cross-sectional view corresponding to line D in FIG. 1 of an alternative air gap configuration of the semiconductor structure, according to an illustrative embodiment.

### DETAILED DESCRIPTION

Illustrative embodiments are described herein in the context of illustrative methods for configuring air-gap isolated stacked semiconductor device architectures, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment,” as well as any other variations, appearing in various places throughout the specification are not necessarily all referring to the same embodiment. The term “positioned on” means that a first element, such as a first structure, is present on a second element, such as a second structure, where intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. In FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm node and beyond), next generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is a continued desire for further scaling and reducing the size of FETs.

As discussed above, various techniques may be used to reduce the size of FETs, including using fin-shaped channels in FinFET devices, using stacked nanosheet channels formed over a semiconductor substrate, using next-generation SFET devices, and using stacked device architectures, possibly incorporating different types of FET (e.g., a FinFET device stacked with a GAA FET).

With continuous area scaling, conventional techniques for designing and fabricating vertically stacked transistors face significant challenges related to increased leakage currents, elevated capacitance, and high contact resistance. Some embodiments described herein provide an air gap formed between source/drain regions of vertically stacked transistors. These and other embodiments advantageously reduce electrical interference and leakage between the stacked transistors, reduce parasitic capacitance, and improve overall device performance by enhancing isolation between the top and bottom transistor layers.

Although embodiments described herein are discussed in connection with nanosheet stacks, the embodiments are not necessarily limited thereto and may similarly apply to nanowire stacks.

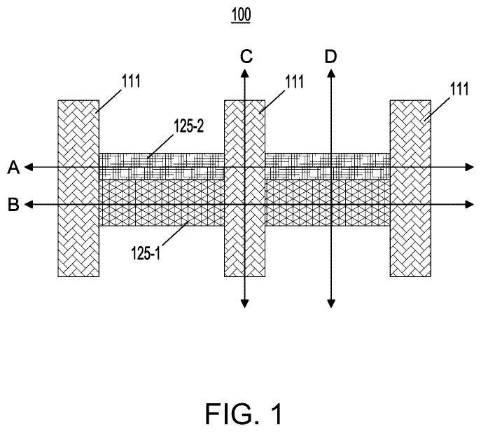

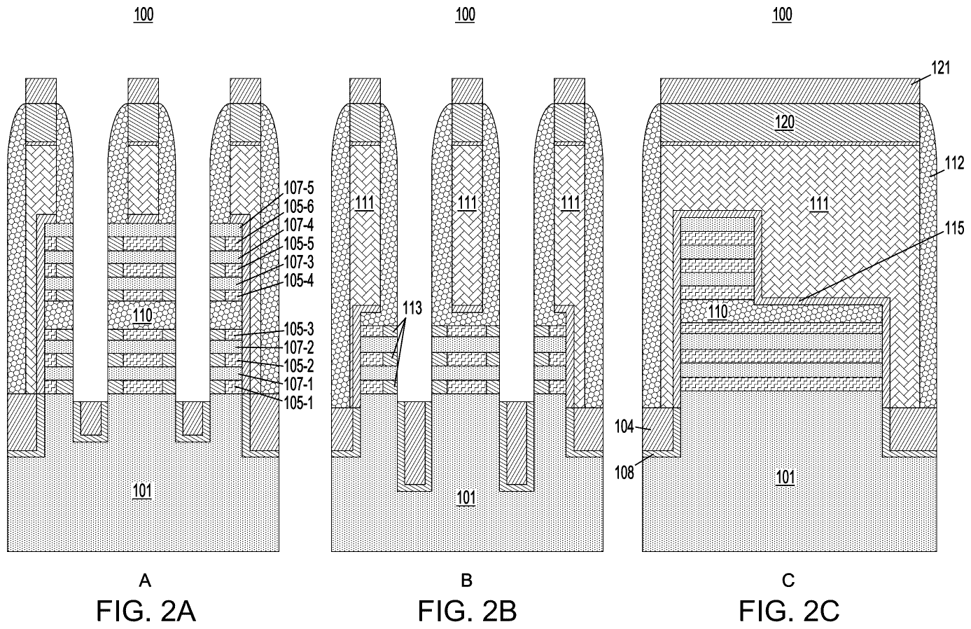

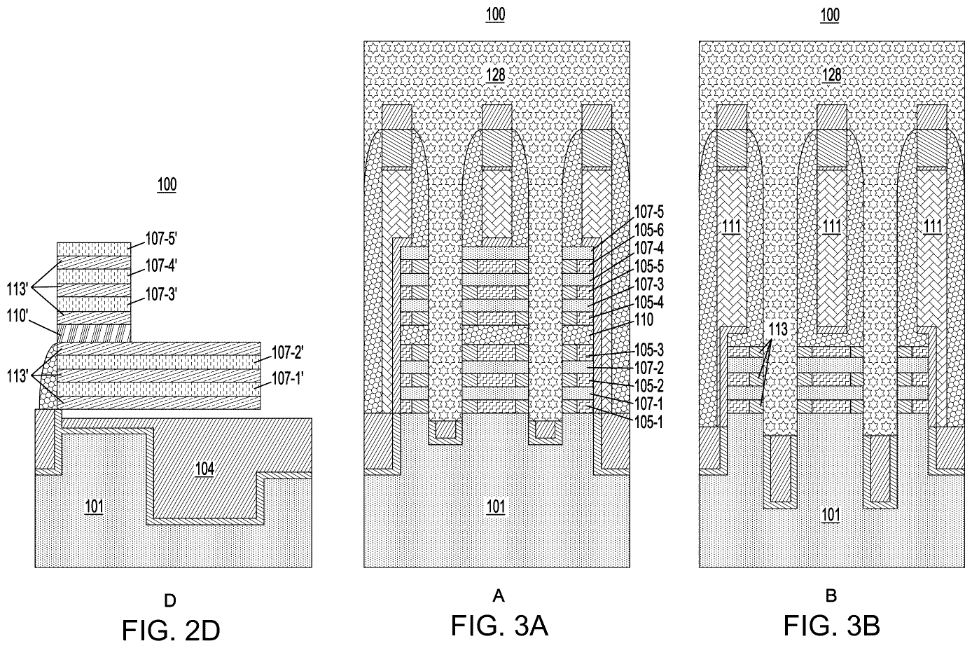

Referring to FIG. 1 and to the cross-sectional views in FIGS. 2A-2D, which respectively correspond to the lines A, B, C, and D in FIG. 1, a semiconductor structure 100 includes a first transistor active area 125-1 and a second transistor active area 125-2. In some embodiments, the first transistor active area 125-1 is associated with a first plurality of source/drain regions, while the second transistor active area 125-2 can be associated with a second plurality of source/drain regions. In such embodiments, the first plurality of source/drain regions may have a different doping type (e.g., N+) than the second plurality of source/drain regions (e.g., P+), as described in more detail elsewhere herein.

The semiconductor structure 100 also includes a stacked structure comprising sacrificial layers 105-1, 105-2, 105-3, 105-4, 105-5, and 105-6 (collectively “sacrificial layers 105”) and channel layers 107-1, 107-2, 107-3, 107-4, and 107-5 (collectively “channel layers 107”). In an illustrative embodiment, the sacrificial layers 105 comprise SiGe and the channel layers 107 comprise silicon. The stacked structure also includes a middle dielectric isolation (MDI) layer 110.

The MDI layer 110 may comprise, for example, silicon oxide (SiOₓ) (where x is for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof.

While six sacrificial layers 105 and five channel layers 107 are shown, the embodiments described herein are not necessarily limited to the shown number of sacrificial layers 105 and channel layers 107. There may be more or less layers in the same alternating configuration depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can also be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside” or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

In FIG. 2D, the channel layers 107, the MDI layer 110, and the inner spacers 113 are labeled as 107′, 110′, and 113′, respectively, to indicate that they are out-of-plane with respect to line D. This notation is applied to other out-of-plane elements throughout the figures and the text below for clarity.

Isolation regions 104 (for example, shallow trench isolation (STI) regions) comprising dielectric material fill in recessed portions of the semiconductor substrate 101 between the nanosheet stacks of sacrificial layers 105 and the channel layers 107. A corresponding liner layer 108 is also formed between the isolation regions 104 and the semiconductor substrate 101. The liner layer 108 may be formed of SiN or another suitable material such as SiBCN, SiCOH, SiNCH, etc. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof.

A protective liner 115 is formed on sidewalls of the sacrificial layers 105 and the channel layers 107, and on the top surfaces of the uppermost sacrificial layers 105, as shown in FIG. 2C, for example. The protective liner 115 may be formed of SiN, SiO2, or another suitable material such as SiBCN, SiCOH, SiNCH, etc. As shown in FIG. 2C, the semiconductor structure 100 comprises an L-shaped profile, where the channel layers 107 below the MDI layer 110 are wider than the channel layers 107 above the MDI layer 110.

Inner spacers 113 are formed between portions of the top and bottom surfaces of the MDI layer 110, and on sides of the stacked structures of the sacrificial layers 105 and the channel layers 107, as shown. Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN.

Dummy gate portions 111 are formed on and around the protective liner 115 of the nanosheet stacks of the sacrificial layers 105 and channel layers 107. The dummy gate portions 111 include, but are not necessarily limited to, an amorphous silicon (a-Si) layer. The dummy gate portions 111 are formed using any suitable deposition techniques, such as chemical vapor deposition (CVD), plasma-enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), followed by a planarization step such as a chemical mechanical planarization (CMP) process.

Gate spacers 112 are positioned on opposite lateral sides of the dummy gate portions 111. In an illustrative embodiment, the gate spacers 112 are formed from the same or similar material to that of the inner spacers 113.

Hardmask (HM) layers 120 and 121 are formed on the dummy gate portions 111. The HM layer 120 comprises, for example, a nitride such as SiN or other nitride material. The HM layer 121 can be formed of any suitable material such as oxide and/or nitride materials such as SiN, a multi-layer of SiN and SiO₂, or other suitable material.

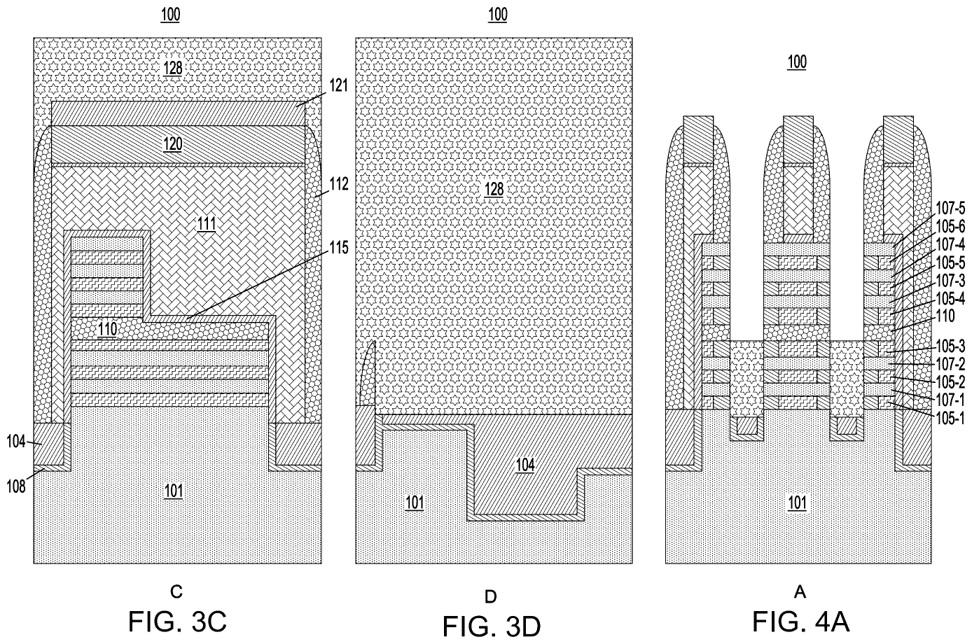

FIGS. 3A-3D show cross-sectional views of the semiconductor structure 100 following formation of a dielectric layer 128. The dielectric layer 128 is formed by depositing dielectric material on exposed portions of the semiconductor substrate 101 between the sacrificial layers 105 and channel layers 107. In some embodiments, the dielectric material may comprise, for example, oxide and/or nitride materials such as SiN, a multi-layer of SiN and SiO₂, or other suitable material, and is deposited using deposition techniques such as, for example, CVD, PECVD, RFCVD, PVD, ALD, MBD, PLD, and/or LSMCD. In some embodiments, the dielectric layer 128 can be formed by deposition of a self-planarizing dielectric material such as spin-on-glass (SOG). In some embodiments, a planarization process (e.g., a CMP process) can be performed to remove excess portions of the dielectric layer 128 deposited on top of the HM layer 121 and gate spacers 112.

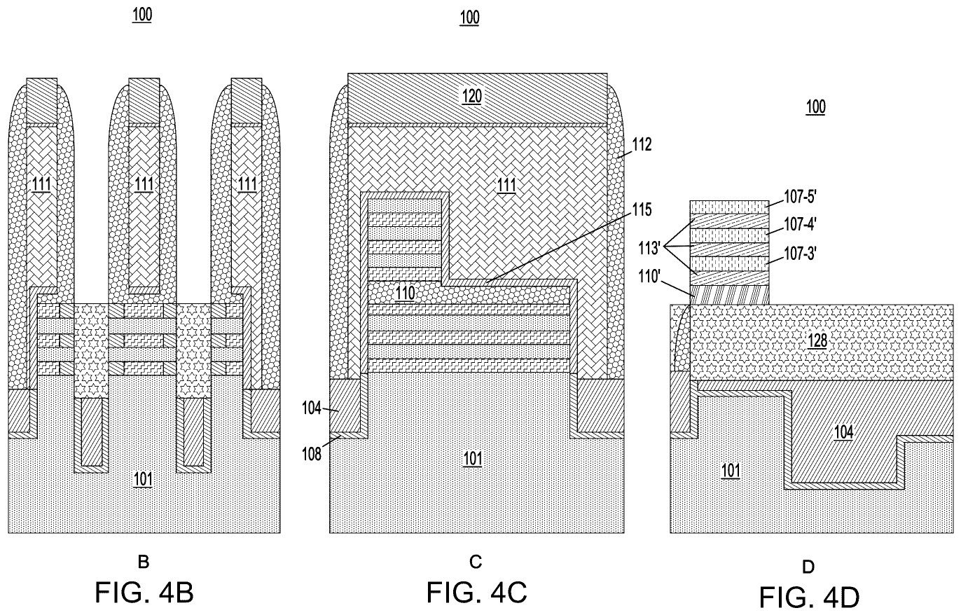

FIGS. 4A-4D show cross-sectional views of the semiconductor structure 100 following recessing of the dielectric layer 128. The dielectric layer 128 is recessed down to approximately a level corresponding to the bottom surface of the MDI layer 110 using, for example, a dry etching process such as reactive ion etching (RIE) or ion beam etching (IBE), a wet chemical etching process, or a combination of these etching processes.

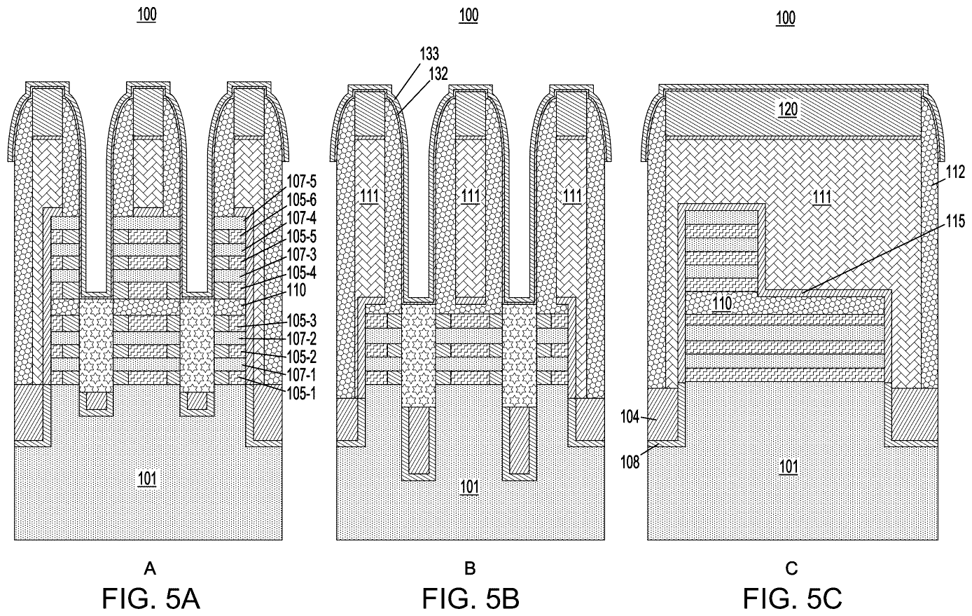

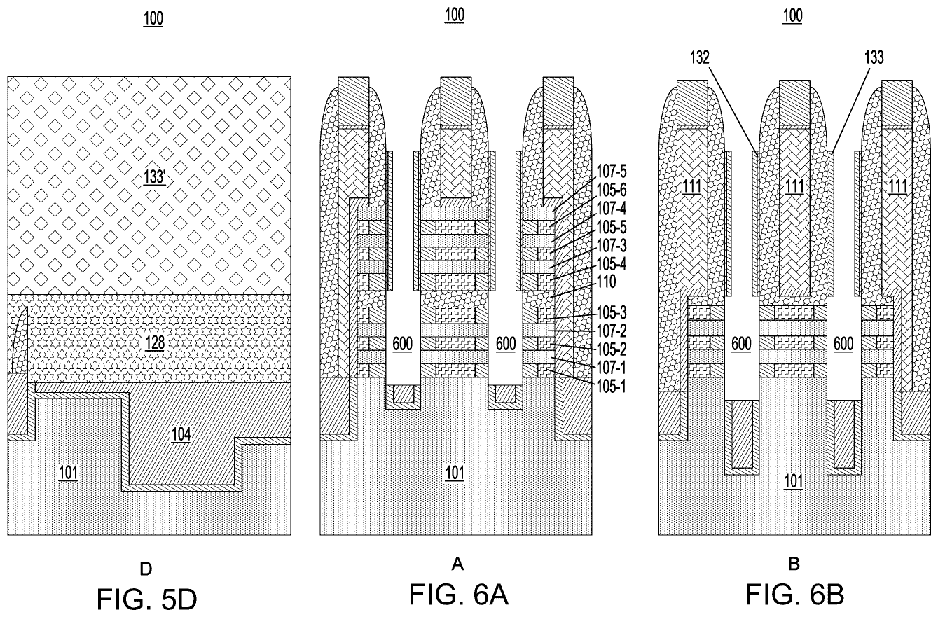

FIGS. 5A-5D show cross-sectional views of the semiconductor structure 100 following formation of an oxide layer 132 and a blocking spacer layer 133. The oxide layer 132 can be deposited on the sidewalls of the gate spacers 112 and the exposed surfaces of the HM layer 120 and the dielectric layer 128. The oxide layer 132 can be applied using a CVD deposition process, for example. The blocking spacer layer 133 can be formed of a nitride, such as SiN or other nitride material. The blocking spacer layer 133 covers the exposed surfaces of the oxide layer 132 and the dielectric layer 128.

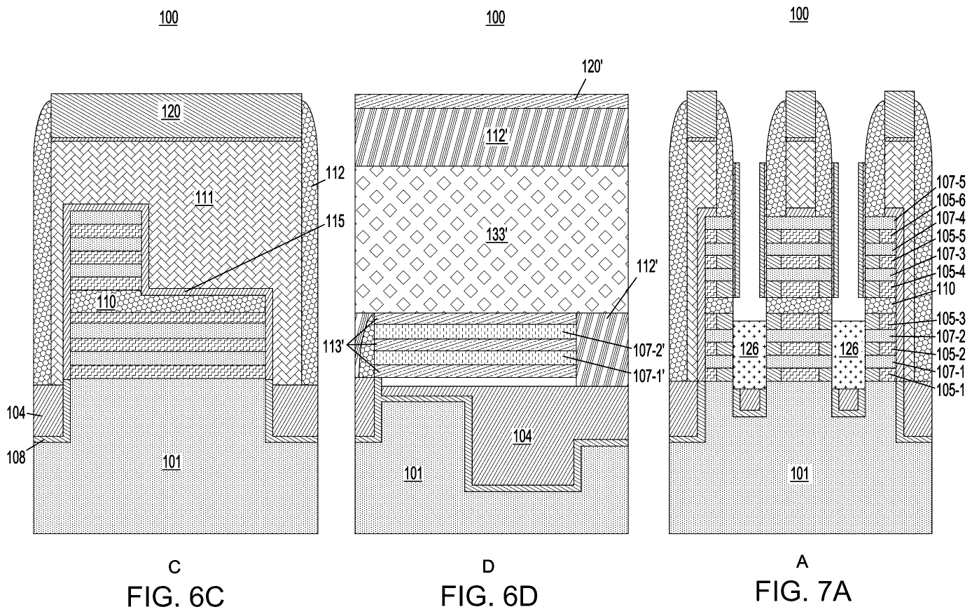

FIGS. 6A-6D show cross-sectional views of the semiconductor structure 100 following partial removal of the oxide layer 132, the blocking spacer layer 133, and removal of the dielectric layer 128. The top portions of the blocking spacer layer 133 are removed down to a level below the HM layers 120 and 121, as shown in FIGS. 6A and 6B. Horizontal portions of the oxide layer 132 and the blocking spacer layer 133 are positioned above the dielectric layer 128, exposing a top surface of the dielectric layer 128. The portions of the oxide layer 132 and the blocking spacer layer 133 can be removed using one or more etching processes such as a dry etching process (e.g., RIE, IBE, or atomic layer etching (ALE)), a wet etching process (e.g., isotropic etching), or a combination of these etching processes.

The remaining portions of the dielectric layer 128 are then removed to create openings 600 between the sacrificial layers 105 and the channel layers 107 that are below the MDI layer 110. The dielectric layer 128 can be removed using, for example, a dry etching process (such as RIE or IBE), a wet chemical etching process, or a combination of these etching processes.

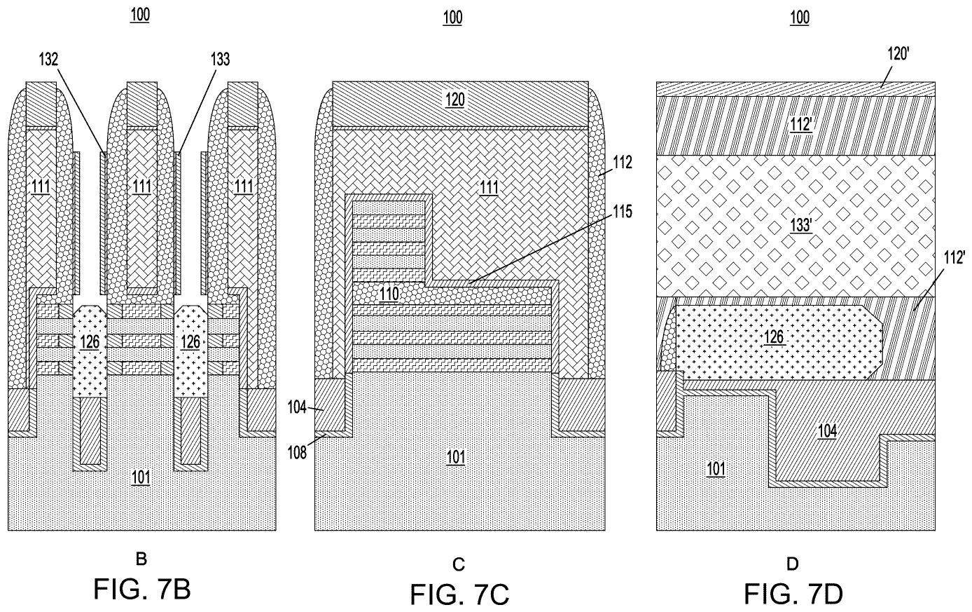

FIGS. 7A-7D show cross-sectional views of the semiconductor structure 100 following formation of bottom source/drain region 126. The bottom source/drain region 126 can be epitaxially grown from the exposed surfaces of the channel layers 107 in the bottom portions of the openings 600 as shown in FIGS. 7A and 7B.

In some embodiments, the bottom source/drain region 126 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As), and antimony (Sb), and p-type dopants may be selected from a group of boron (B), boron fluoride (BF2), gallium (Ga), indium (In), and thallium (Tl). In some embodiments, the epitaxy process used to form the bottom source/drain region 126 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si: C) can be doped during deposition (in-situ doped) by adding dopants, such as n-type dopants (e.g., phosphorus or arsenic) or p-type dopants (e.g., boron or gallium), depending on the type of transistor to be formed.

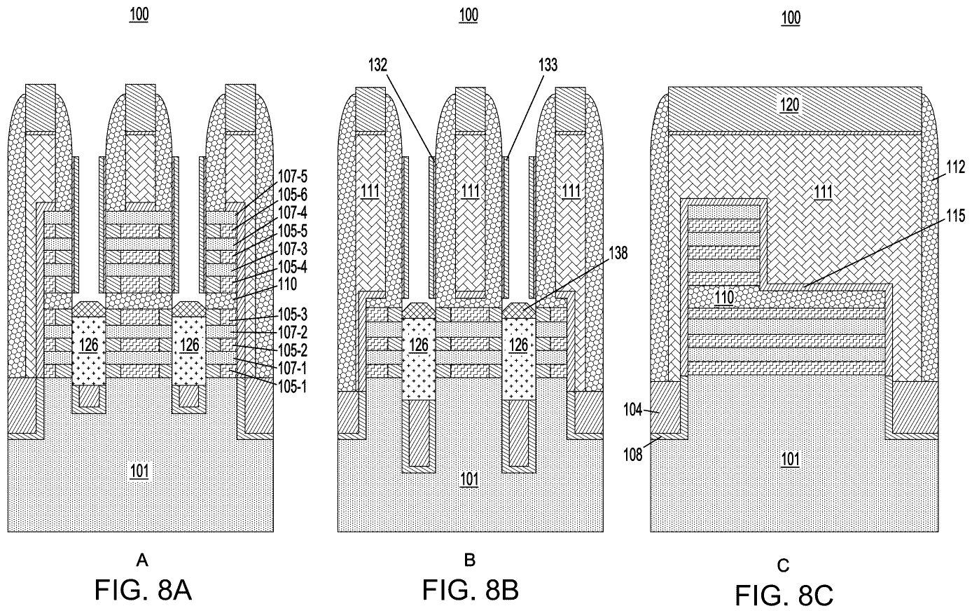

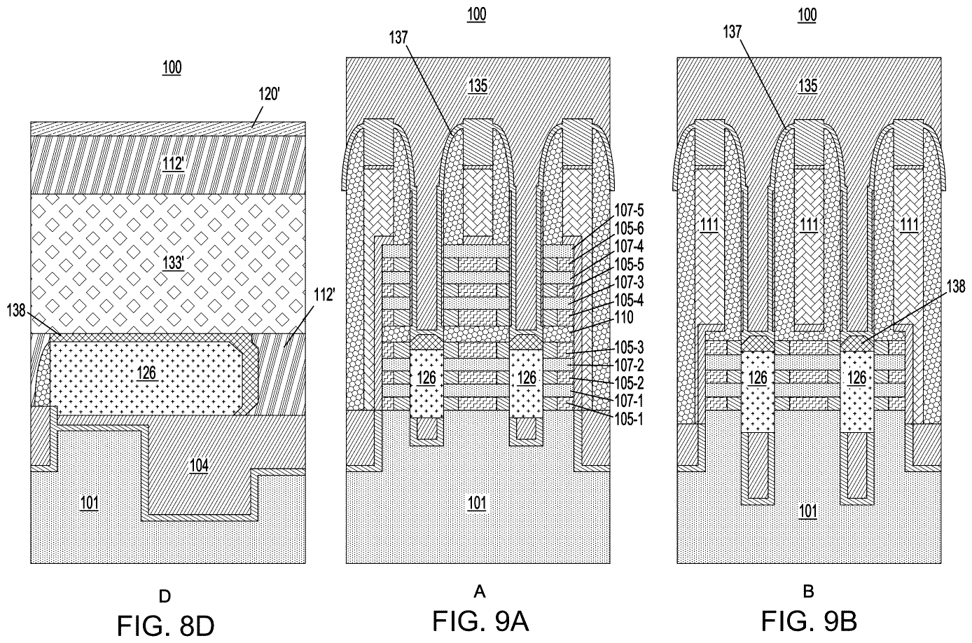

FIGS. 8A-8D show cross-sectional views of the semiconductor structure 100 following formation of a sacrificial layer 138. The sacrificial layer 138 can be formed using any deposition technique. For example, in some embodiments, the sacrificial layer 138 can be epitaxially grown from the bottom source/drain region 126 or formed using one or more deposition techniques (e.g., CVD, PECVD, RFCVD, PVD, ALD, MBD, etc.), and/or using an ion injection process (IIP). In illustrative embodiments, the sacrificial layer 138 can comprise, for example, SiGe, III-V semiconductor material, or other semiconductor material.

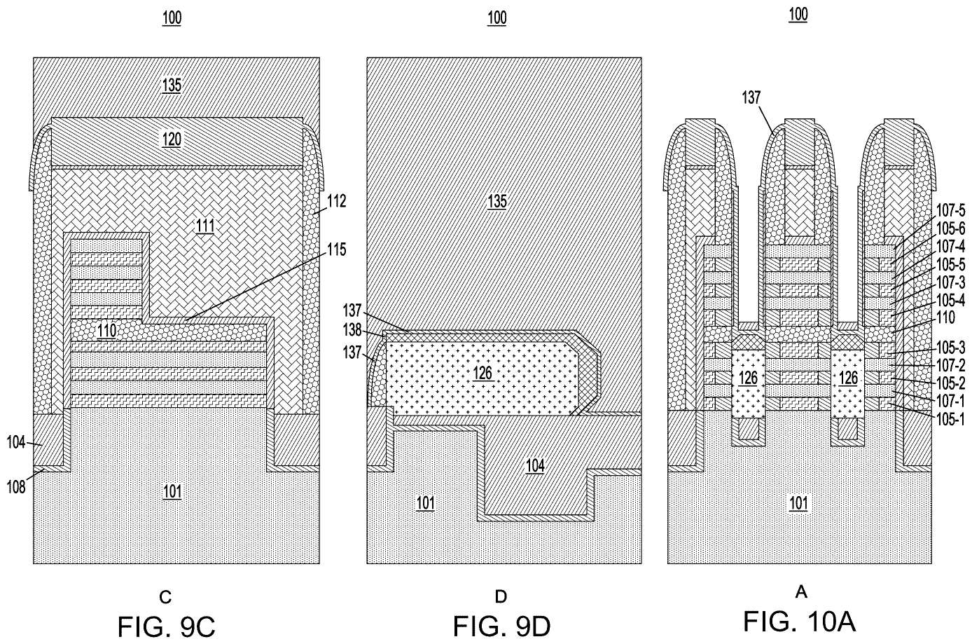

FIGS. 9A-9D show cross-sectional views of the semiconductor structure 100 following formation of an interlayer dielectric (ILD) layer 135 including an ILD liner 137. The ILD liner 137 can be formed using similar techniques and materials as the oxide layer 132, for example. The ILD liner 137 covers the exposed surfaces of semiconductor structure 100, including the MDI layer 110, the gate spacers 112, the HM layer 120, and the sacrificial layer 138.

The ILD layer 135 fills vacant spaces of the semiconductor structure 100 and extends above the top surfaces of the HM layer 120 and the ILD liner 137. The ILD layer 135 can comprise a dielectric material that is deposited using deposition techniques such as, for example, CVD, PECVD, RFCVD, PVD, ALD, MBD, PLD, and/or LSMCD. In some embodiments, the ILD layer 135 can be formed using similar processes and materials as dielectric layer 128, for example.

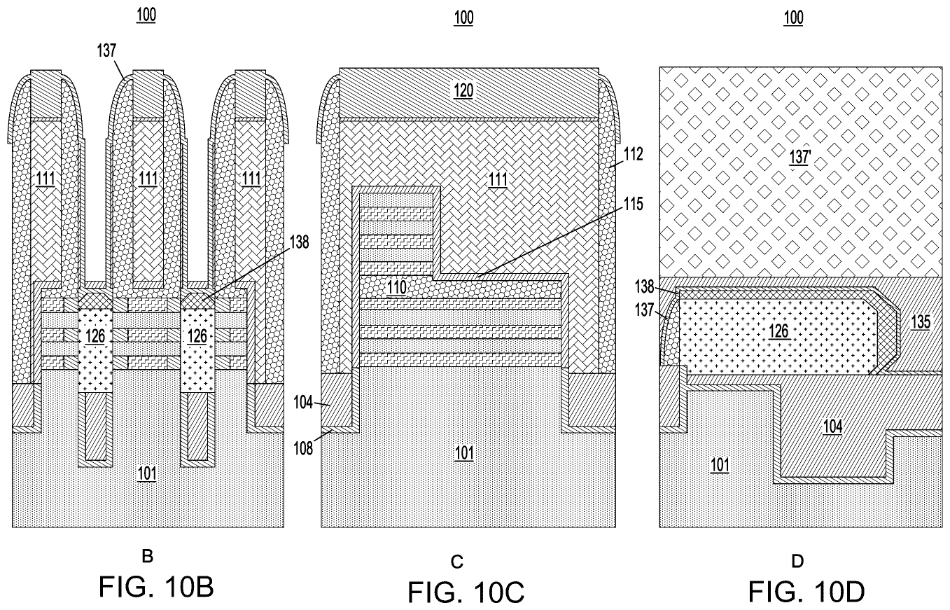

FIGS. 10A-10D show cross-sectional views of the semiconductor structure 100 following partial removal of the ILD layer 135. In some embodiments, the ILD layer 135 is recessed to approximately a level corresponding to a top surface of the MDI layer 110, using, for example, a dry etching process using a RIE or IBE process, a wet chemical etching process or a combination of these etching processes. Following the recessing, portions of the ILD layer 135 above the sacrificial layer 138 remain, as shown in FIGS. 10A, 10B, and 10D.

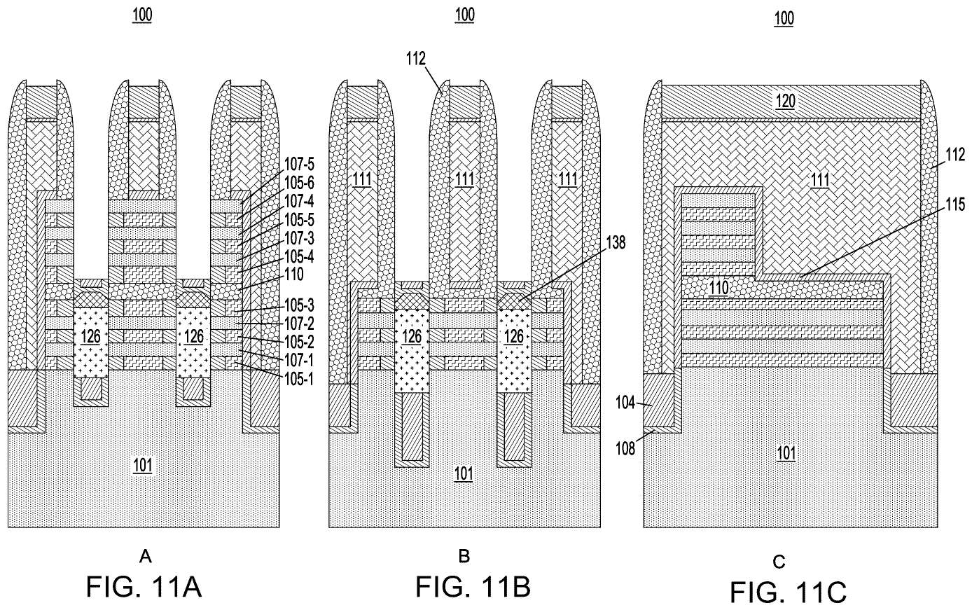

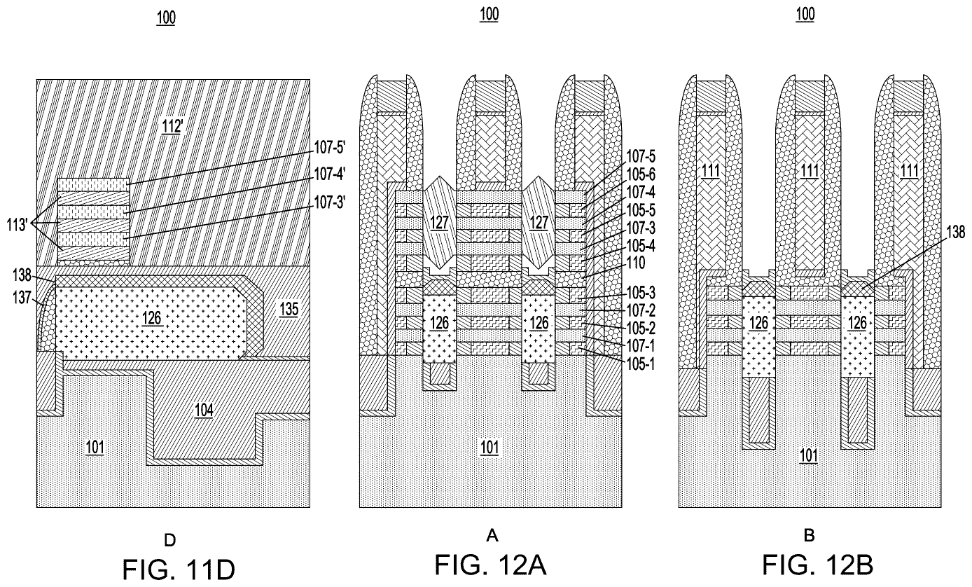

FIGS. 11A-11D show cross-sectional views of the semiconductor structure 100 following partial removal of the ILD liner 137. In particular, the top portions of the ILD liner 137 are removed down to a level corresponding to the top surface of the ILD layer 135. The portions of the ILD liner 137 can be removed using similar techniques as for the removal of the portions of the blocking spacer layer 133.

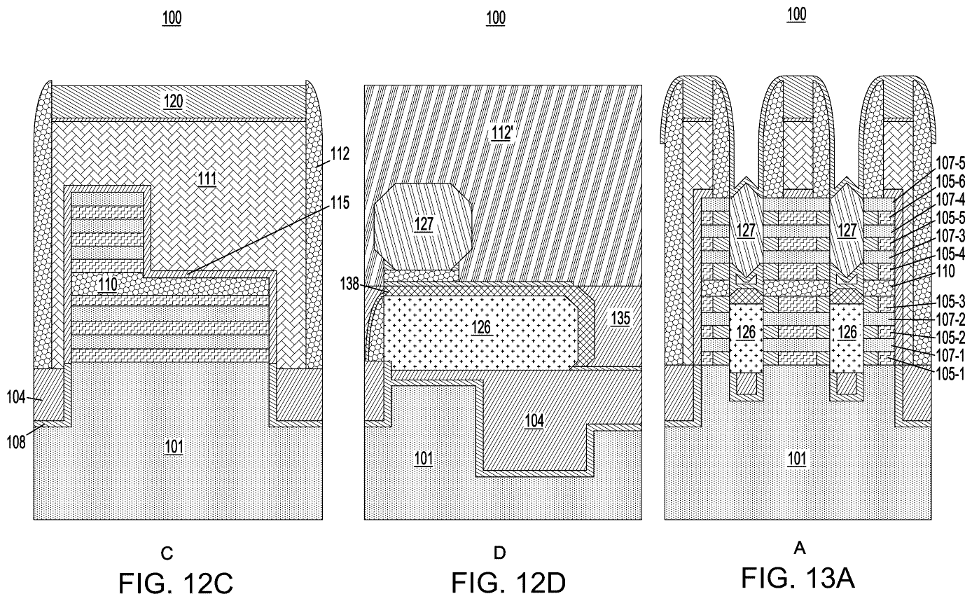

FIGS. 12A-12D show cross-sectional views of the semiconductor structure 100 following further removal of the ILD layer 135 and formation of top source/drain region 127. In particular, portions of the ILD layer 135 above the sacrificial layer 138 are removed using, for example, an epi pre-clean process. The top source/drain region 127 can be epitaxially grown from the exposed surfaces of the channel layers 107 that are above the MDI layer 110 using similar techniques as for the bottom source/drain region 126.

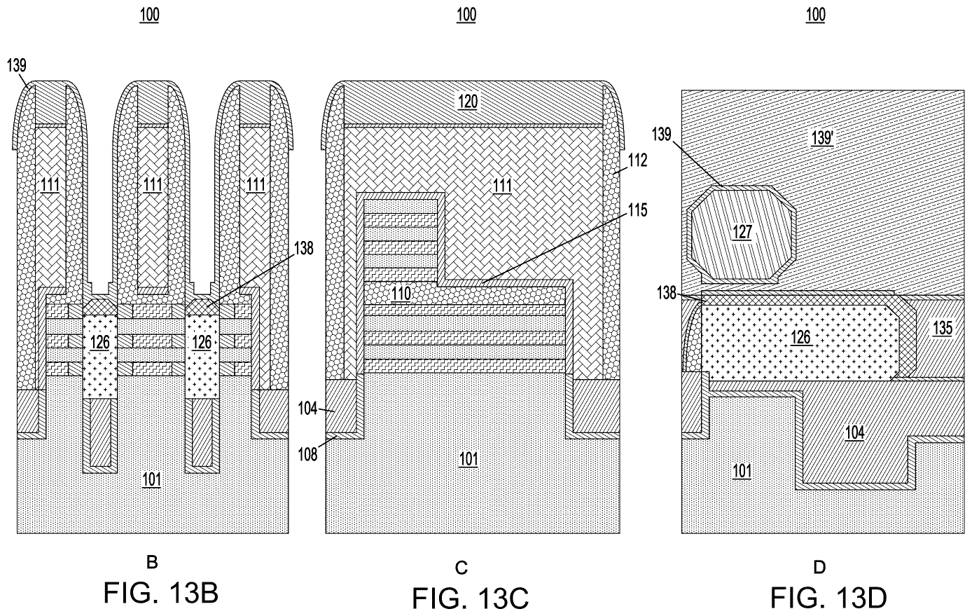

FIGS. 13A-13D show cross-sectional views of the semiconductor structure 100 following formation of an isolation layer 139. In illustrative embodiments, an isolation layer 139 is formed using conformal deposition of a dielectric material that is deposited to cover exposed surfaces of the top source/drain region 127, the gate spacers 112, the HM layer 120, and the ILD layer 135. The isolation layer 139 can be formed using similar techniques and materials as described above with respect to the liner layer 108, for example.

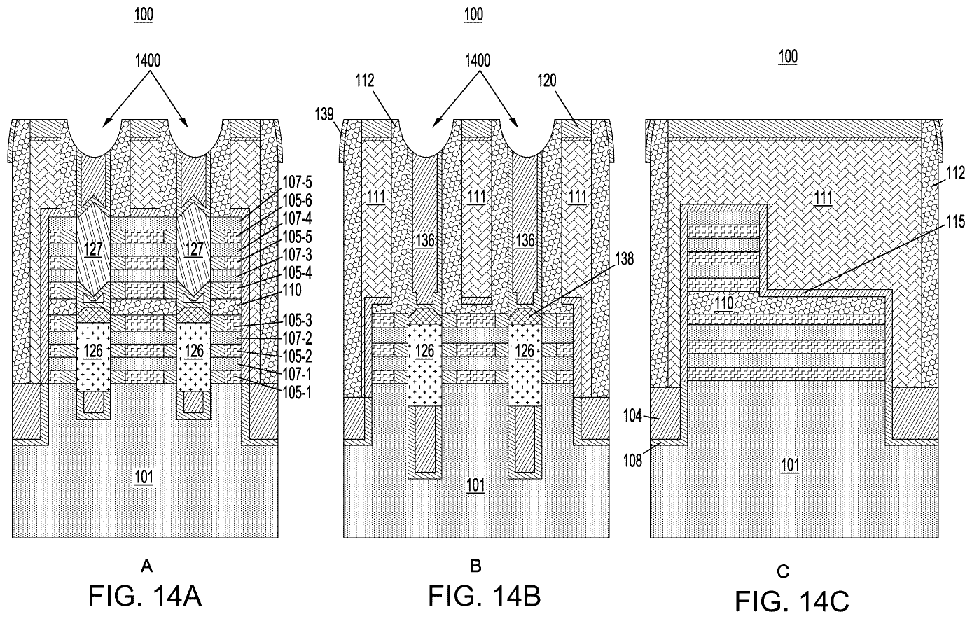

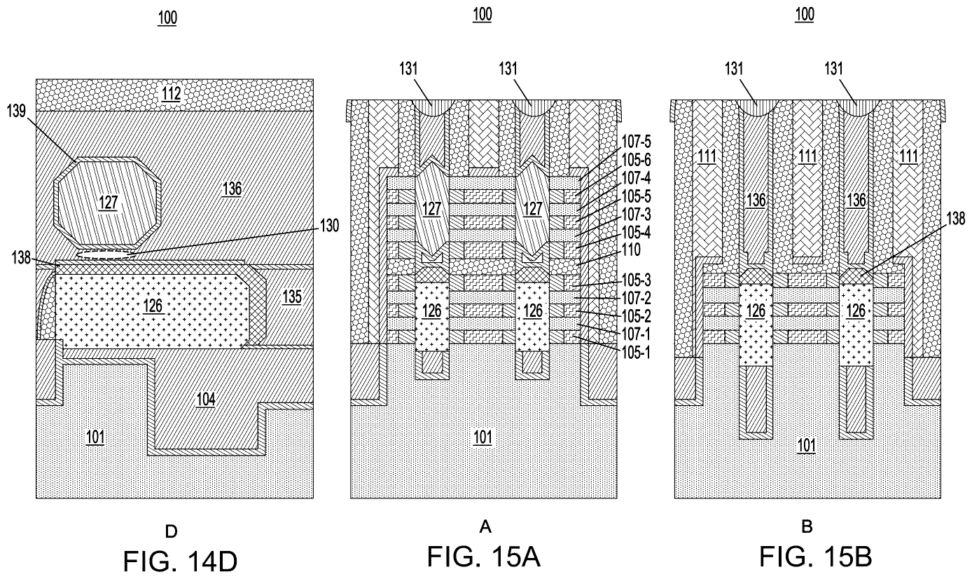

FIGS. 14A-14D show cross-sectional views of the semiconductor structure 100 following formation of an additional ILD layer 136 and trenches 1400. In some embodiments, the additional ILD layer 136 is formed using similar processes and materials as the ILD layer 135. For example, the additional ILD layer 136 can be formed by depositing dielectric material to a level above the HM layer 120, followed by a planarization process to recess the additional ILD layer 136 to be level with the top surface of the HM layer 120. An air gap 130 can optionally be formed below the top source/drain region 127, as shown in FIG. 14D.

The trenches 1400 are formed by removing portions of the additional ILD layer 136, the gate spacers 112, and the isolation layer 139 above the source/drain regions 126 and 127, as shown in FIGS. 14A and 14B. The trenches 1400 can be formed using one or more etching processes including dry etching processes (e.g., RIE or IBE), wet chemical etching processes, or a combination of these etching processes.

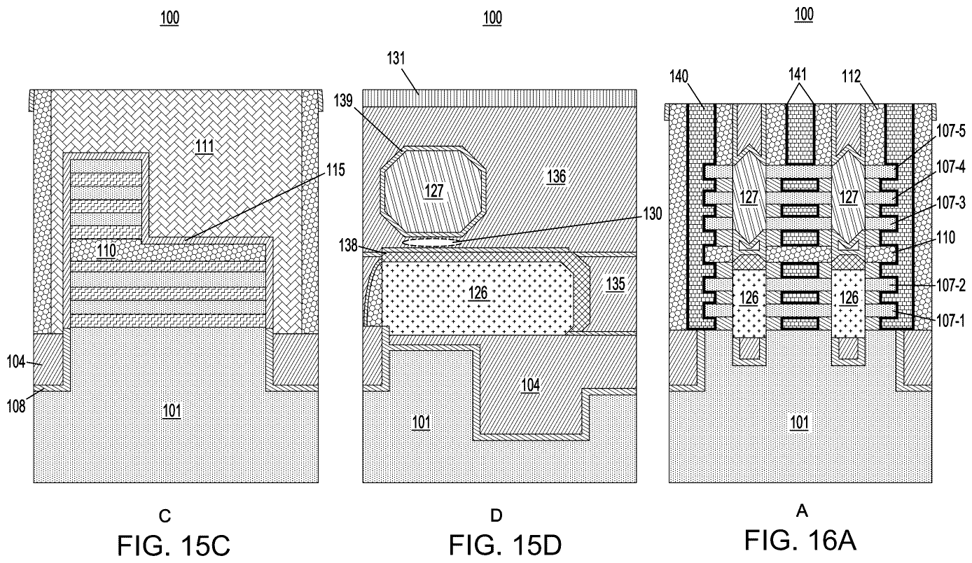

FIGS. 15A-15D show cross-sectional views of the semiconductor structure 100 following formation of a stopping layer 131 and a planarization process. The material of the stopping layer 131 can comprise oxide and/or nitride materials, such as SiN, a multi-layer of SiN and SiO₂, or other suitable material. The stopping layer 131 is formed using any suitable deposition process such as a high-density plasma (HDP) process.

Following the formation of the stopping layer 131, a planarization process (e.g., CMP) is performed to remove the HM layers 120 and 121, thereby exposing the dummy gate portions 111.

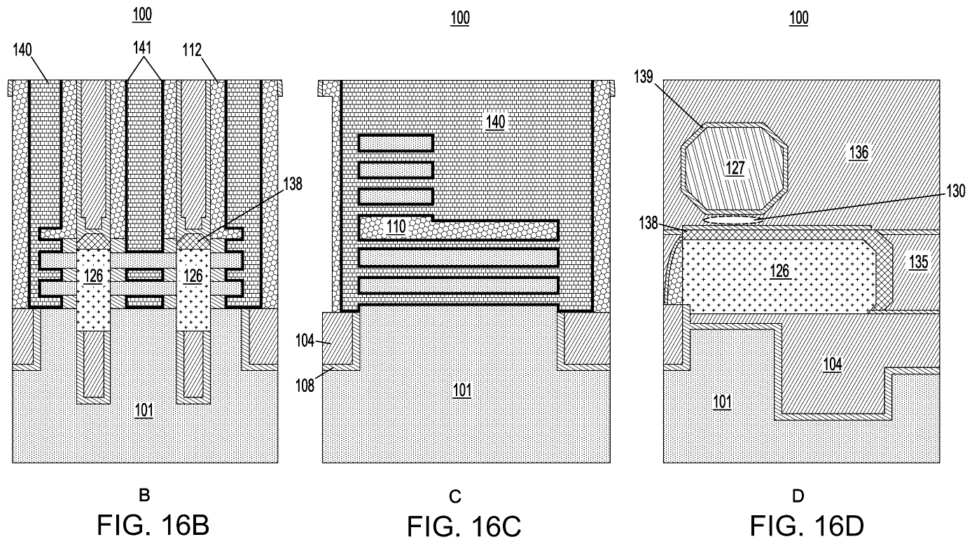

FIGS. 16A-16D show cross-sectional views of the semiconductor structure 100 following a replacement metal gate (RMG) process. For example, the RMG process can include selectively removing the dummy gate portions 111 and the sacrificial layers 105 to create vacant areas, and forming gate structures 140 in the resulting vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended, and the gate structures 140 are formed in the vacant areas left by removal of the dummy gate portions 111 and the sacrificial layers 105. In illustrative embodiments, each gate structure 140 can have a gate dielectric layer 141 such as, for example, a high-K dielectric layer such as, but not limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k dielectric materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate structures 140 each include a metal gate portion including a work-function metal (WFM) layer. The WFM layer includes, but is not necessarily limited to, titanium nitride (TiN), tantalum nitride (TaN) or ruthenium (Ru) for a pFET, and TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN for an nFET, which can be deposited on the gate dielectric layer. The metal gate portions can also each further include a gate metal layer such as, but not limited to, metals such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer 141. It should be appreciated that various other materials may be used for the metal gate portions as desired.

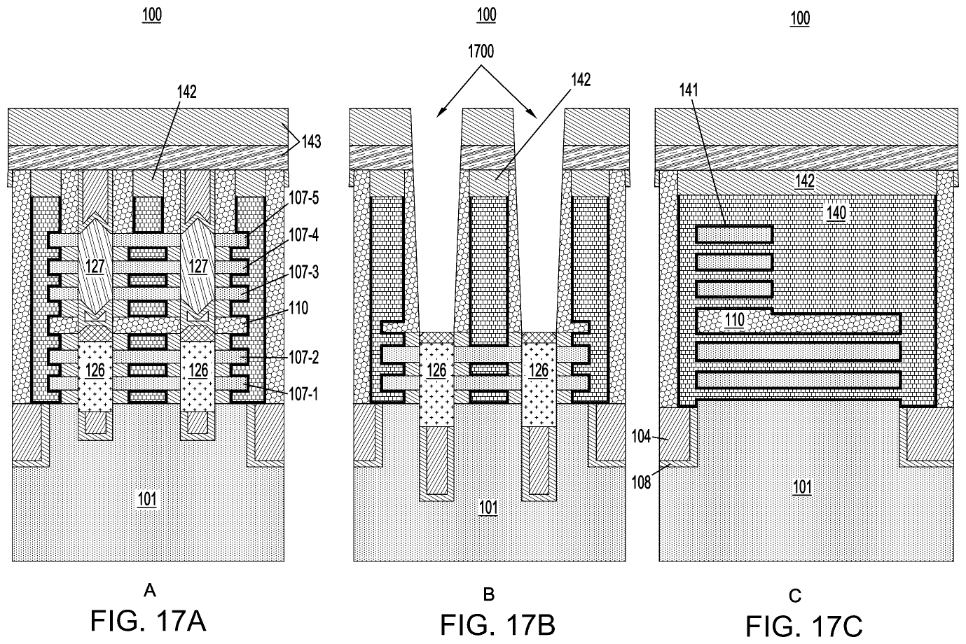

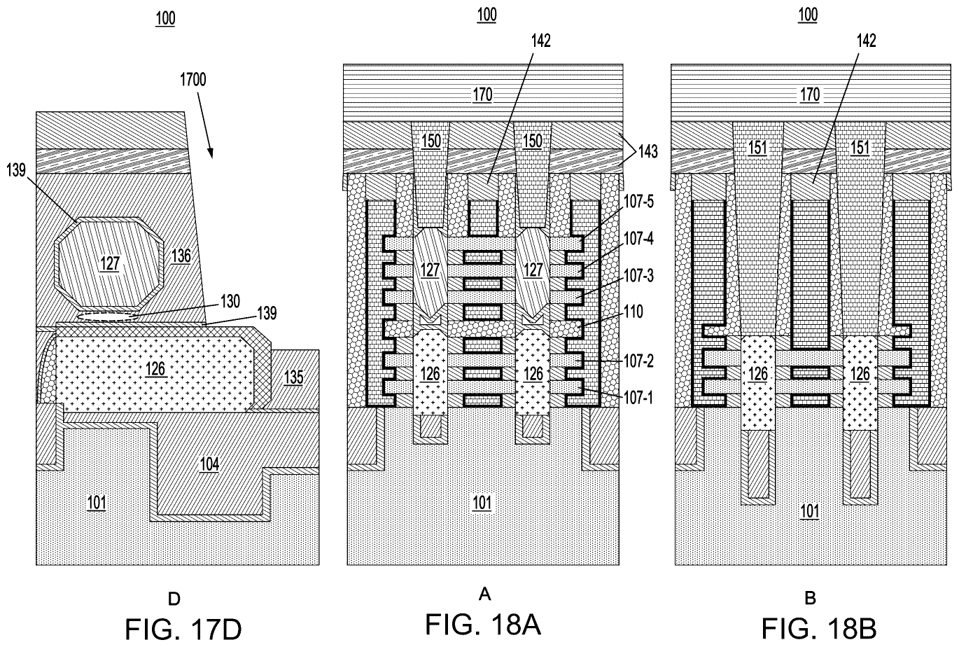

FIGS. 17A-17D show cross-sectional views of the semiconductor structure 100 following formation of deep trenches 1700. In some embodiments, the gate structures 140 and the gate dielectric layer 141 are recessed to below the top surfaces of the gate spacers 112. A gate protection layer 142 is formed above the gate structures 140 and between the gate spacers 112. One or more additional ILD layers 143 are deposited above the gate spacers 112, the gate protection layer 142, and the additional ILD layer 136.

The deep trenches 1700 extend through the gate protection layer 142, and the additional ILD layer 136 to expose respective surfaces of the sacrificial layer 138. The deep trenches 1700 can be formed using one or more etching processes including dry etching processes such as RIE or IBE, wet chemical etching processes, or a combination of these etching processes.

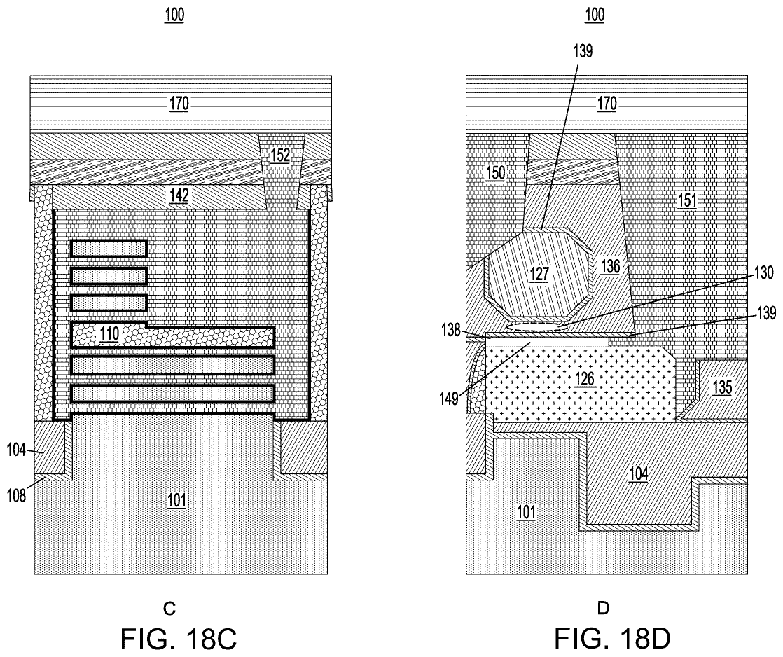

FIGS. 18A-18D show cross-sectional views of the semiconductor structure 100 following further processing steps. The further processing steps include steps for removing at least portions of the sacrificial layer 138 and forming top source/drain contacts 150, bottom source/drain contacts 151, a gate contact 152, and frontside back-end-of-line (BEOL) interconnects 170.

At least portions of the sacrificial layer 138 can be removed selective to the bottom source/drain region 126, the isolation layer 139, ILD layer 135, and the additional ILD layer 136. The sacrificial layer 138 can be removed using, for example, a selective dry or wet etch process.

Following removal of the sacrificial layer 138, bottom source/drain contacts 151 are formed in areas corresponding to the deep trenches 1700. The bottom source/drain contacts 151 may include a silicide layer such as Ni, Ti, NiPt, etc., a metal adhesion layer such as TiN, and a conductive metal fill layer such as tungsten (W), aluminum (Al), copper (Cu), cobalt (Co), ruthenium (Ru), molybdenum (Mo), etc., and can be deposited using, for example, a deposition technique such as CVD, PECVD, RFCVD, PVD, ALD, MBD, PLD, LSMCD, sputtering and/or plating, followed by planarization processes, such as CMP, to remove excess portions of the bottom source/drain contacts 151 from on top of the additional ILD layers 143.

Following the formation of the bottom source/drain contacts 151, an air gap 149 is formed in a portion of the space corresponding to where the sacrificial layer 138 was removed. In some embodiments, the deposition rate of materials used to form the bottom source/drain contacts 151 are controlled to ensure that the air gap 149 is properly formed.

The top source/drain contacts 150 and the gate contact 152 are formed through the additional ILD layer 136 and the additional ILD layers 143. The top source/drain contacts 150 extend down and contact respective portions of the top source/drain region 127, and the gate contact 152 extends down and contacts one of the gate structures 140. The top source/drain contacts 150 and the gate contact 152 can be formed using similar techniques and materials as the bottom source/drain contacts 151, for example.

The frontside BEOL interconnects 170 are formed on the additional ILD layers 143 and include various BEOL interconnect structures. In some embodiments, forming the frontside BEOL interconnects 170 can include forming one or more frontside vias that connect corresponding portions of the bottom source/drain contacts 151, the top source/drain contacts 150, and/or the gate contact 152 to the frontside BEOL interconnects 170. The material of the frontside vias can comprise a conductive material such as W, Al, Cu, Co, Ru, Mo, or any other suitable conductive material.

The arrangement of the top source/drain contacts 150, the bottom source/drain contacts 151, and the gate contact 152 shown in FIGS. 18A-18D is merely an example; it is to be appreciated that alternative arrangements are also possible.

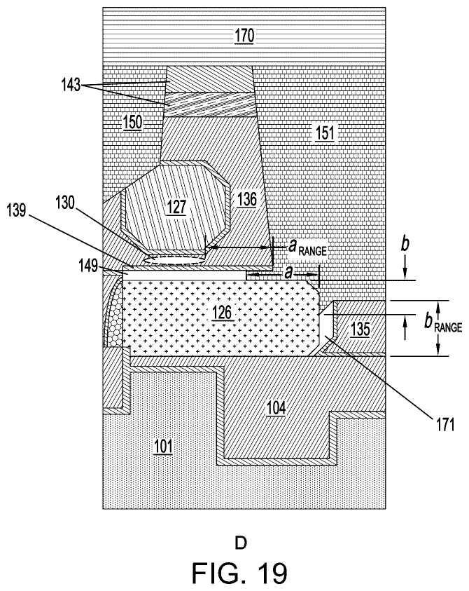

FIG. 19 depicts a cross-sectional view corresponding to line D in FIG. 1 of an alternative air gap configuration of the semiconductor structure 200. The semiconductor structure 200 is formed using similar techniques as for semiconductor structure 100 except that semiconductor structure 200 includes an air gap 171 adjacent to the bottom source/drain region 126. The distance, a, corresponds to an overlap between the bottom source/drain region 126 and the material of the bottom source/drain contacts 151 in the horizontal direction, and the distance, b, corresponds to an overlap between the bottom source/drain region 126 and the material of the bottom source/drain contacts 151 in the vertical direction. It is to be appreciated that the amount of overlap of a and b can be adjusted depending on the application. For example, the amount of overlap of a can be adjusted so that extension of the material of the bottom source/drain contacts 151 into the air gap 149 ends within the range of a_{RANGE} and the amount of overlap of b can be adjusted so that the extension of the contact material of the bottom source/drain contacts 151 into the air gap 171 ends within the range of b_{RANGE}, as shown in FIG. 19. In other embodiments, the amount of overlap of a can extend so that it at least partially vertically overlaps with the top source/drain region 127.

In some embodiments, the height, length, and/or width of the air gap 149 and/or the air gap 171 can have any range in which the bottom source/drain region 126 and the top source/drain region 127 are present. In some embodiments, the air gap can be configured in various ways, including an air gap formed above the bottom source/drain region 126, on one or more sides of the bottom source/drain region 126, or surrounding the bottom source/drain region 126.

The air gap configurations described for semiconductor structures 100 and 200 are merely examples, and other air gap configurations are also possible depending on the application.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes a first transistor including a first source/drain region and a second transistor, vertically stacked on the first transistor, including a second source/drain region. The semiconductor device includes an isolation layer positioned between the first transistor and the second transistor and an air gap positioned between the first source/drain region and the isolation layer.

The semiconductor device of the illustrative embodiment advantageously reduces parasitic capacitance and electrical leakage between stacked transistors by incorporating an air gap between the first source/drain region and the isolation layer, which can effectively improve the overall performance and efficiency of the semiconductor device.

In embodiments, the semiconductor device may further include a source/drain contact connected to the first source/drain region.

In embodiments, the source/drain contact may extend between a portion of a top side of the first source/drain region and a portion of a bottom side of the isolation layer. Such embodiments advantageously reduce contact resistance by increasing the contact area between the source/drain contact and the top surface of the first source/drain region.

In embodiments, the source/drain contact may extend down one or more vertical sides of the first source/drain region. Such embodiments advantageously reduce contact resistance by increasing the contact area between the source/drain contact and the one or more vertical sides of the first source/drain region.

In embodiments, the source/drain contact may include at least one conducting material.

In embodiments, the isolation layer may include at least one of an oxide material, a nitride material, a metal material, and a semiconductor material.

In embodiments, the air gap may be positioned along a top side of the first source/drain region and at least one other side of the first source/drain region. Such embodiments can advantageously further isolate operating voltages applied to the first source/drain region by positioning the air gap along multiple sides of the first source/drain region.

In embodiments, the air gap may surround at least two sides of the first source/drain region.

In embodiments, the first source/drain region may include at least one of a silicon material, a silicon germanium material, a germanium material, and an alloy material.

In embodiments, the second transistor may be bonded to the first transistor by a bonding oxide material.

In embodiments, the first transistor and the second transistor may be part of a logic circuit and/or a static random access memory circuit.

In embodiments, the semiconductor device may further include an additional air gap positioned between the isolation layer and the second source/drain region. Such embodiments advantageously further reduce interlayer capacitance and leakage current between the stacked devices as the additional air gap acts as an additional electric barrier between the first transistor and the second transistor.

In embodiments, the first transistor and the second transistor may comprise a different type of resistor (e.g., the first device may comprise a FinFET device, and the second transistor may comprise a GAA FET device).

In embodiments, the first transistor and the second transistor may comprise the same type of resistor.

In another illustrative embodiment, a semiconductor device includes an L-shaped stacked transistor architecture comprising a first transistor having a first source/drain region and a second transistor having a second source/drain region. The semiconductor device further includes an isolation layer positioned between the first transistor and the second transistor, and an air gap positioned between a portion of the first source/drain region and the isolation layer.

The semiconductor device of the illustrative embodiment advantageously reduces parasitic capacitance and electrical leakage between stacked transistors by incorporating an air gap between the first source/drain region and the isolation layer, which can effectively improve the overall performance and efficiency of the semiconductor device.

In embodiments, the air gap may vertically overlap an entirety of the second source/drain region.

In embodiments, the semiconductor device may further include a source/drain contact connected to the first source/drain region.

In embodiments, the source/drain contact may extend between a portion of a top side of the first source/drain region and a portion of a bottom side of the isolation layer. Such embodiments advantageously reduce contact resistance by increasing the contact area between the source/drain contact and the top surface of the first source/drain region.

In embodiments, the source/drain contact may extend down one or more vertical sides of the first source/drain region. Such embodiments advantageously reduce contact resistance by increasing the contact area between the source/drain contact and one or more vertical sides of the first source/drain region.

In embodiments, the air gap may be positioned along a top side of the first source/drain region and at least one other side of the first source/drain region. Such embodiments can advantageously further isolate operating voltages applied to the first source/drain region by positioning the air gap along multiple sides of the first source/drain region.

In another exemplary embodiment, a method includes forming a first transistor comprising a first source/drain region, forming a sacrificial layer over the first source/drain region, and forming a second transistor, vertically stacked over the first transistor, comprising a second source/drain region. The method includes removing the sacrificial layer to form an opening between the first source/drain region and an isolation layer positioned between the first transistor and the second transistor and forming a source/drain contact connected to the first source/drain region. The source/drain contact partially fills the opening, thereby creating an air gap between at least a top side of the first source/drain region and the isolation layer.

The method of the illustrative embodiment advantageously reduces interlayer capacitance and leakage current between vertically stacked transistors by creating an air gap between the first source/drain region and the isolation layer. This can improve electrical performance by mitigating interference between the top and bottom transistors, thereby enhancing overall device efficiency and reliability.

In embodiments, the source/drain contact may include at least one contact material, and wherein forming the source/drain contact comprises controlling a deposition rate of contact material to configure a shape of the air gap. Such embodiments advantageously allow for precise control over the formation of the air gap through controlled deposition rates of contact material to ensure effective isolation and reduced parasitic capacitance.

The above-described embodiments advantageously provide an air gap between source/drain regions of vertically stacked transistors (e.g., in CMOS structures), which can reduce capacitance and improve electrical leakage during operation. These and other embodiments can effectively isolate the operating voltages applied to the source/drain regions of the vertically stacked transistors, thereby mitigating interference between the top and bottom transistors. For example, at least one embodiment includes forming an air gap along one or more sides of the bottom source/drain region. In such embodiments, the air gap can reduce interlayer capacitance and leakage current between the stacked devices while also improving bottom contact resistance by increasing contact area, for example.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor comprising a first source/drain region;
a second transistor, vertically stacked on the first transistor, comprising a second source/drain region;
an isolation layer positioned between the first transistor and the second transistor; and
an air gap positioned between the first source/drain region and the isolation layer.

2. The semiconductor device of claim 1, further comprising a source/drain contact connected to the first source/drain region.

3. The semiconductor device of claim 2, wherein the source/drain contact extends between a portion of a top side of the first source/drain region and a portion of a bottom side of the isolation layer.

4. The semiconductor device of claim 2, wherein the source/drain contact extends down one or more vertical sides of the first source/drain region.

5. The semiconductor device of claim 2, wherein the source/drain contact comprises at least one conducting material.

6. The semiconductor device of claim 1, wherein the isolation layer comprises at least one of an oxide material, a nitride material, a metal material, and a semiconductor material.

7. The semiconductor device of claim 1, wherein the air gap is positioned along a top side of the first source/drain region and at least one other side of the first source/drain region.

8. The semiconductor device of claim 1, wherein the air gap surrounds at least two sides of the first source/drain region.

9. The semiconductor device of claim 1, wherein the first source/drain region comprises at least one of a silicon material, a silicon germanium material, a germanium material, and an alloy material.

10. The semiconductor device of claim 1, wherein the second transistor is bonded to the first transistor by a bonding oxide material.

11. The semiconductor device of claim 1, wherein the first transistor and the second transistor are part of a logic circuit and/or a static random access memory circuit.

12. The semiconductor device of claim 1, further comprising an additional air gap positioned between the isolation layer and the second source/drain region.

13. A semiconductor device comprising:
an L-shaped stacked transistor architecture comprising a first transistor having a first source/drain region and a second transistor having a second source/drain region;
an isolation layer positioned between the first transistor and the second transistor; and
an air gap positioned between a portion of the first source/drain region and the isolation layer.

14. The semiconductor device of claim 13, wherein the air gap vertically overlaps an entirety of the second source/drain region.

15. The semiconductor device of claim 13, further comprising:
a source/drain contact connected to the first source/drain region.

16. The semiconductor device of claim 15, wherein the source/drain contact extends between a portion of a top side of the first source/drain region and a portion of a bottom side of the isolation layer.

17. The semiconductor device of claim 15, wherein the source/drain contact extends down one or more vertical sides of the first source/drain region.

18. The semiconductor device of claim 13, wherein the air gap is positioned along a top side of the first source/drain region and at least one other side of the first source/drain region.

19. A method comprising:
forming a first transistor comprising a first source/drain region;
forming a sacrificial layer over the first source/drain region;
forming a second transistor, vertically stacked over the first transistor, comprising a second source/drain region;
removing the sacrificial layer to form an opening between the first source/drain region and an isolation layer positioned between the first transistor and the second transistor; and
forming a source/drain contact connected to the first source/drain region, wherein the source/drain contact partially fills the opening, thereby creating an air gap between at least a top side of the first source/drain region and the isolation layer.

20. The method of claim 19, wherein the source/drain contact comprises at least one contact material, and wherein forming the source/drain contact comprises controlling a deposition rate of contact material to configure a shape of the air gap.
